(19) United States
(12) Patent Application Publication
(10) Pub. No.: US 2007/0026610 A1
(43) Pub. Date: Feb. 1, 2007

(54) SEALING METHOD FOR ELECTRONIC DEVICES FORMED ON A COMMON SEMICONDUCTOR SUBSTRATE AND CORRESPONDING CIRCUIT STRUCTURE

(75) Inventors: Emilio Camerlenghi, Bergamo (IT); Alfonso Maurelli, Sulbiate (MI) (IT); Daniela Peschiaroli, Milano (IT); Paola Zabberoni, Monza(MI) (IT)

Correspondence Address: ALLEN, DYER, DOPPELT, MILBRATH & GILCHRIST P.A., 1401 CITRUS CENTER 255 SOUTH ORANGE AVENUE, P.O. BOX 3791, ORLANDO, FL, 32802-3791, US

(73) Assignee: STMicroelectronics S.r.l., Agrate Brianza (MI) (IT)

(21) Appl. No.: 11/457,948

(22) Filed: Jul. 17, 2006

Related U.S. Application Data
(63) Continuation-in-part of application No. 10/971,774, filed on Oct. 22, 2004, now Pat. No. 7,078,294.

(30) Foreign Application Priority Data
Oct. 22, 2003 (EP) 03425687.5

(51) Int. Cl. H01L 21/336; H01L 21/8234

(52) U.S. Cl. 438/258; 438/275

(57) ABSTRACT

An integrated circuit includes a semiconductor substrate including first and second portions, with first electronic devices adjacent the first portion. Each first electronic device includes a first region comprising at least one first conductive layer projecting from the semiconductor substrate. First protective spacers are adjacent sidewalls of the first regions of the first electronic devices. The first protective spacers are defined by first and second sealing layers adjacent one another. Second electronic devices are adjacent the second portion of the semiconductor substrate. Each second electronic device includes a second region comprising a second conductive layer projecting from the semiconductor substrate. Second protective spacers are adjacent sidewalls of the second regions of the second electronic devices. The second protective spacers are defined by other portions of the second sealing layer. The second sealing layer has a thickness less than a thickness of the first sealing layer.

### RELATED APPLICATION

The present application is a continuation-in-part of U.S. patent application Ser. No. 10/971,774 filed Oct. 22, 2004, the disclosure of which is incorporated herein by reference.

### FIELD OF THE INVENTION

The present invention relates to integrated circuits with electronic devices having different types of sealing structures. The present invention relates more particularly, but not exclusively, to a differential sealing method for non-volatile memory cells with a double polysilicon level and transistors associated therewith, formed on a common semiconductor substrate. The following description is made with reference to this field of application for convenience of illustration only.

### BACKGROUND OF THE INVENTION

The integration on a common semiconductor substrate of different electronic devices, such as traditional transistors and non-volatile memory cells with a double polysilicon level for example, presents the problem of reconciling the different needs for sealing these two different types of electronic devices. Sealing refers to the manufacturing process where one or more layers are formed after the polysilicon layer forming the gate regions of the transistors and memory cells have been formed. This manufacturing process seals these electronic devices.

Typically, memory cells undergo a high quality sealing step to ensure the retention properties of the charge stored in the floating gate region. For transistors, a protection layer formed as part of this sealing step is to provide protection from the subsequent process steps.

A prior art approach provides the use of two different photolithographic masks to first define the gate regions in a memory matrix, and then those of the circuitry even if the order is not significant. Afterwards, the simultaneous oxidation of both electronic devices occurs, thus sealing the devices by a single sealing layer.

Although advantageous, this approach has several drawbacks as the size of the electronic devices decreases. In fact, the continuous reduction in the size of the electronic devices pushes transistors to require thinner sealing layers, and heat treatments with lower temperatures. This is in contrast to memory cells requiring thicker layers in addition to higher quality requirements.

### SUMMARY OF THE INVENTION

In view of the foregoing background, an object of the present invention is to provide an independent sealing method for electronic devices formed on a common semiconductor substrate that does not jeopardize individually optimized performances and reliability of these devices, and may not require further steps or masks beyond those for a traditional process flow.

This and other objects, advantages and features in accordance with the present invention are provided by an integrated circuit comprising a semiconductor substrate including first and second portions, and a plurality of first electronic devices adjacent the first portion of the semiconductor substrate. Each first electronic device may includes a first region comprising at least one first conductive layer projecting from the semiconductor substrate.

First protective spacers may be adjacent the sidewalls of the first regions of the plurality of first electronic devices. The first protective spacers may be defined by first and second sealing layers adjacent one another. A plurality of second electronic devices may be adjacent the second portion of the semiconductor substrate. Each second electronic device may include a second region comprising at least one second conductive layer projecting from the semiconductor substrate. Second protective spacers may be adjacent sidewalls of the second regions of the plurality of second electronic devices. The second protective spacers may be defined by other portions of the second sealing layer. The second sealing layer may have a thickness less than a thickness of the first sealing layer.

Another embodiment of the invention is directed to an integrated circuit comprising a semiconductor substrate including first and second portions, a dielectric layer adjacent the first portions of the semiconductor substrate, and a plurality of first electronic devices adjacent the dielectric layer. Each first electronic device may include a first region comprising at least one first conductive layer projecting from the dielectric layer. A first sealing layer may be adjacent the plurality of first electronic devices.

A plurality of second electronic devices may be adjacent the second portion of the semiconductor substrate. Each second electronic device may include a second region comprising at least one second conductive layer projecting from the semiconductor substrate. A second sealing layer may be adjacent the plurality of second electronic devices and adjacent the first sealing layer. The second sealing layer may have a thickness less than a thickness of the first sealing layer.

Yet another aspect of the invention is directed to a method for making integrated circuits as defined above.

### BRIEF DESCRIPTION OF THE DRAWINGS

The features and advantages according to the invention will be apparent from the following description of an embodiment thereof given by way of a non-limiting example with reference to the attached drawings. In the drawings:

FIGS. 1 to 5 are cross-sectional views of different portions of a semiconductor substrate based upon a manufacturing method according to the invention.

### DETAILED DESCRIPTION OF THE PREFERRED EMBODIMENTS

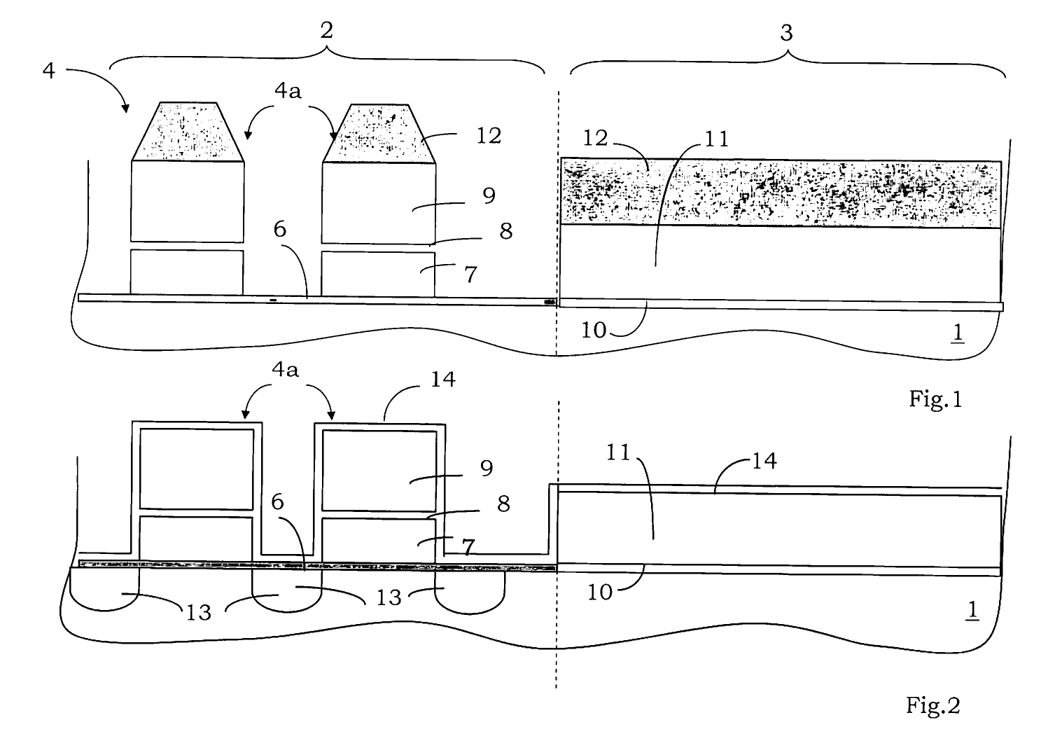

With reference to FIGS. 1 to 5, a method for sealing electronic devices formed on a common semiconductor substrate in an independent manner, and the corresponding circuit structure will now be described. The method steps described below do not form a complete process flow for manufacturing integrated circuits. The present invention can be implemented together with the integrated circuit manufacturing techniques presently used in this field, and only those commonly used process steps necessary to understand the present invention are presented.

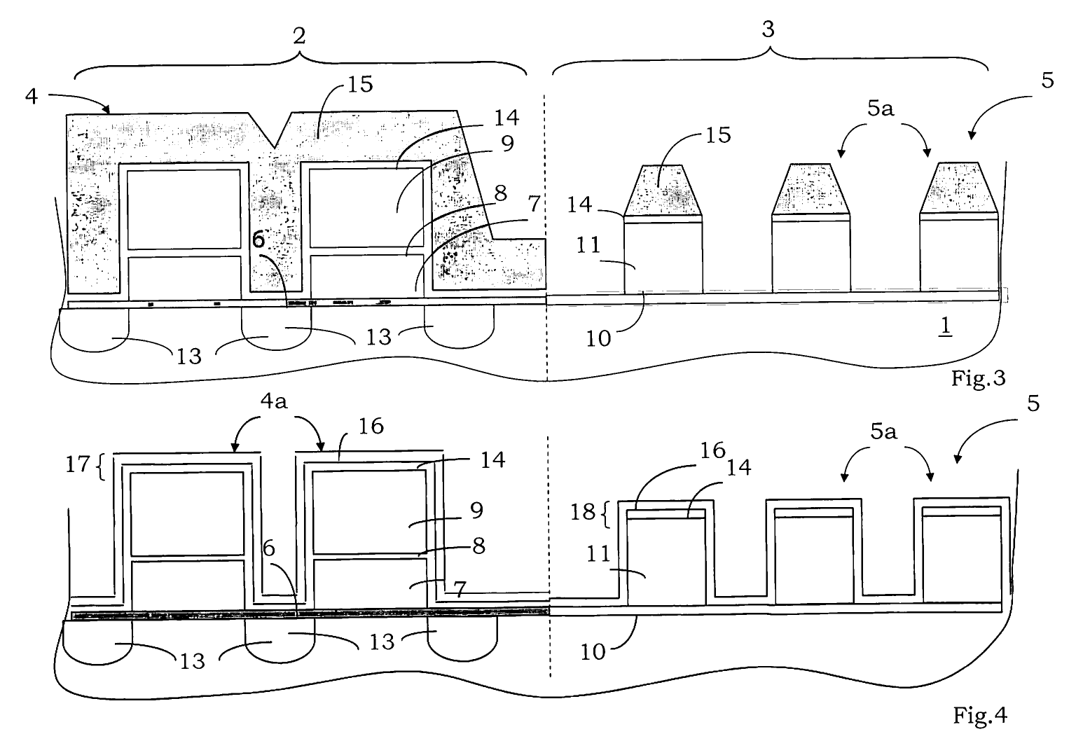

The figures representing cross sections of portions of a circuit structure during the manufacturing process are not drawn to scale, but they are drawn instead to show the important features of the invention. Referring now to FIGS. 3 and 4, a circuit structure integrated on a semiconductor substrate 1 comprises a first plurality of electronic devices 4.

The electronic devices 4 are non-volatile memory cells for example. Each of these electronic devices 4 comprises a region 4a projecting from the semiconductor substrate 1. Each region 4a is formed by one or more conductive layers 7, 9 that are electrically insulated from each other by an insulating layer 8. The region 4a is coated with a first sealing layer 17 having a first thickness. The first sealing layer 17 seals these electronic devices 4.

The first sealing layer 17 comprises a plurality of insulating layers 14, 16. Moreover, the first sealing layer 17 advantageously covers a portion of the exposed semiconductor substrate 1 between the single electronic devices 4.

The semiconductor substrate 1 also comprises a second plurality of electronic devices 5. The electronic devices 5 are traditional transistors for example. Each electronic device 5 comprises a region 5a projecting from the semiconductor substrate 1. Each region 5a is formed by at least one conductive layer 11 for example. The region 5a is coated with a second sealing layer 18 for sealing the electronic devices 5.

The second sealing layer 18 has a lower thickness on the semiconductor substrate 1 than the thickness of the first sealing layer 17 covering the electronic devices 4. Moreover, the second sealing layer 18 advantageously has a lower thickness on the vertical walls of the region 5a as compared to the thickness on the top of this region 5a. It is thus possible to form very closely spaced electronic devices 5 allowing for a higher integration scale. The second sealing layer 18 comprises at least one insulating layer 16.

The manufacturing method of a circuit structure according to the invention will now be described. In particular, and by way of example, a method for integrating non-volatile flash memory cells with transistors formed in CMOS technology is described below.

A matrix 2 of cells with associated control circuitry 3 is formed on a semiconductor substrate 1. The cell matrix 2 comprises a plurality of non-volatile memory cells 2, while the control circuitry 3 comprises a plurality of transistors 5.

As it is well known, a manufacturing process of the cell matrix 2 provides the following formation on the semiconductor substrate 1, in cascade, of a first insulating layer 6 such as silicon oxide, a first conductive layer 7 such as polysilicon, a second insulating layer 8 such as silicon oxide, and a second conductive layer 9 such as polysilicon. The formation of a third insulating layer 10 such as silicon oxide, and a third conductive layer 11 such as polysilicon is provided to form the circuitry.

The third conductive layer 11 may be formed simultaneously with the second conductive layer 9. The third insulating layer 10 may be formed simultaneously with the second insulating layer 8.

A first photoresist material layer 12 is then deposited on the whole semiconductor substrate 1. By using a traditional photolithographic technique, the first photoresist layer 12 is etched to define a plurality of gate regions 4a of the memory cells 4. A portion of this first photoresist material layer 12 in the circuitry 3 is left to screen the third conductive layer 11, as shown in FIG. 1.

The definition of the gate regions 4a of the memory cells 4 is completed through an etching step of the second conductive layer 9, of the second insulating layer 8 and of the first conductive layer 7, in cascade. The first insulating layer 6 is also etched, and portions of the semiconductor substrate 1 between the gate regions 4a of the memory cells 4 are exposed. Before removing the first photoresist material layer 12, implants are carried out to form source and drain regions 13 of the memory cells 4.

These implants are configured to improve performance of the memory cells 4. The memory cells 4 are then sealed for forming a first insulating or sealing layer 14 through a high-temperature fast oxidation step. The first sealing layer 14 is between 3 to 15 nm thick, with a typical thickness between 3 and 9 nm, for example.

The sealing layer 14 coats not only the gate regions 4a of the memory cells 4, but also covers portions of the first insulating layer 6 between the gate regions 4a of the memory cells 4, or exposed portions of the semiconductor substrate 1 between the gate regions 4a of the memory cells 4 if the first insulating layer 6 has been removed. This is with the third conductive layer 11 not yet defined in the circuitry 3, as shown in FIG. 2.

A second photoresist material layer 15 is then deposited on the whole semiconductor substrate 1. Using a traditional photolithographic technique, the second photoresist layer 15 is etched to define a plurality of gate regions 5a of the transistors 5. This is while a portion of the second photoresist material layer 15 on the matrix 2 is left to screen the memory cells 4 of the matrix 2, as shown in FIG. 3.

In particular, the circuitry portions not covered by the photoresist layer 15 undergo an etching step to remove the first sealing layer 14, and then an etching step to remove the conductive layer 11. The third insulating layer 10 is also etched, and portions of the semiconductor substrate 1 between the gate regions 5a of the transistors 5 are exposed. After the photoresist layer 15 is removed, transistors 5 are sealed by forming a second thin insulating or sealing layer 16 through an oxidation step. The thickness of the second thin sealing layer 16 is between 1 and 3 nm, with a typical thickness of about 2 nm for example. The second thin sealing layer 16 completely covers the first sealing layer 14.

The second sealing layer 16 coats not only the gate regions 5a of the transistors 5, but also covers portions of a third insulating layer 10 between the gate regions 5a of the transistors 5, or exposed portions of the semiconductor substrate 1 between the gate regions 5a of the transistors 5 if the third insulating layer 10 has been removed.

Therefore, according to the invention, a first sealing layer 17 is thus formed, comprising the first sealing layer 14 and the second sealing layer 16, which completely coats the gate regions 4a of the memory cells 4. A second sealing layer 18 is formed, which completely coats the gate regions 5a of transistors 5 to seal them. The second sealing layer 18 comprises the second sealing layer 16 and portions of the first sealing layer 14 which are on the upper portion of the gate regions 5a of transistors 5.

The definition step of the gate regions 5a of transistors 5, performed after the deposition step of the first sealing layer 14, forms projection regions having portions of the first sealing layer 14 on the top thereof, but not on the side walls thereof. The formation of the second thin sealing layer 16 does not affect the electrical capacities of the memory cells 4. This is because the source and drain regions 13 in the matrix 2 have already been formed. The manufacturing method according to the invention is completed using conventional processing.

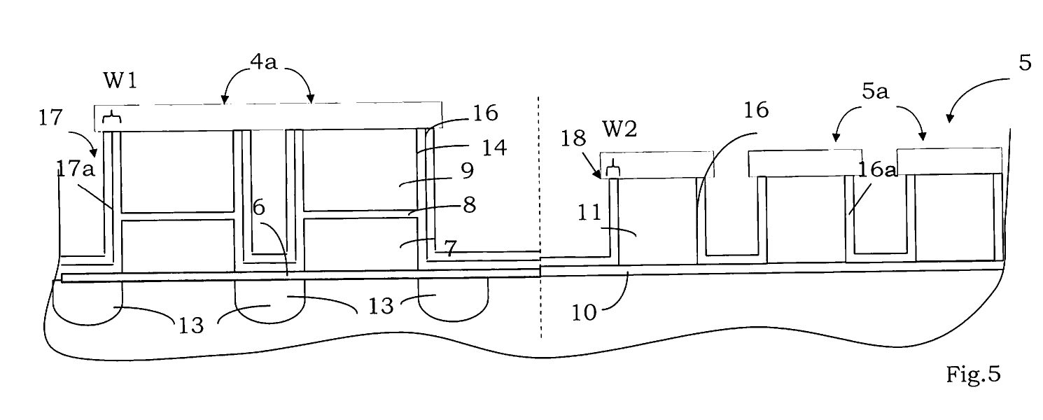

In one embodiment, as shown in FIG. 5, top portions of the first sealing structure 17 are removed up to the top surface of the gate regions 4a of the memory cells 4 and are exposed to permit, for example, the silicidation step of the gate regions 4a. First spacers 17a formed by the first sealing layer 14 and the second sealing layer 16 are formed on sidewalls of the gate regions 4a of the memory cells 4.

Top portions of the second sealing structure 18 are removed up to the top surface of the gate regions 5a of the transistors 5 and are to permit, for example, the silicidation step of the gate regions 5a. Second spacers 18a of the second sealing layer 16 are formed on the sidewalls of the gate regions 5a of the transistors 5. The second spacers 18a have a width W2 narrower than a width W1 of the first spacer 17a.

Therefore, in this embodiment, a first sealing structure 17 is formed by the first spacers 17b. A second sealing structure 18 is advantageously formed by the second spacers 18a.

With the method according to the invention, both traditional memory cells 4 and traditional transistors 5 can be successfully integrated on the common semiconductor substrate 1. This is done without penalizing performance and reliability. The differences with respect to the prior art methods are as follows.

Each definition of the projecting 4a and gate 5a regions, first in the matrix 2 and then in the circuitry 3, is followed by a respective sealing step which is optimized by using sealing layers 14, 16 of different thicknesses and/or materials. The etching step of the conductive layer 11 of the circuitry 3 to define gate regions 5a includes the following: removing the first sealing layer 14 formed also on the conductive layer 11 of the circuit 3; and etching the conductive layer 11, for example, through a highly selective etching step towards the insulating layer 10.

In an alternate embodiment of the method according to the invention, immediately after sealing the memory cells 4, an additional mask is used to leave only the control circuitry 3 exposed. The sealing layer 14 is then removed from the conductive layer 11 before defining the gate regions 5a in the circuitry 3. In this embodiment, the second sealing layer 18 sealing the gate regions 5a of transistors 5 is only formed by the second sealing layer 16. This alternate embodiment is advantageously applied when the materials used to form the sealing layer 14 for sealing the memory cells 4 are different and should be removed to allow the conductive layer 11 to be correctly etched to define gate regions 5a in the circuitry 3.

In conclusion, the method according to the invention allows topologies of electronic devices requiring different types of sealing to be integrated without jeopardizing individually optimized performance and reliability for each device, with low or no cost. The sealing step of these electronic devices is achieved by sealing layers with different thicknesses, and also including materials being formed immediately after defining the devices of the matrix 2 and the circuitry 3.

That which is claimed is:

1. A method for making an integrated circuit comprising:
forming a plurality of first electronic devices adjacent a first portion of a semiconductor substrate, each first electronic device including a first region comprising at least one first conductive layer projecting from the semiconductor substrate;
forming first protective spacers adjacent sidewalls of the first regions of the plurality of first electronic devices, the first protective spacers defined by first and second sealing layers adjacent one another;
forming a plurality of second electronic devices adjacent a second portion of the semiconductor substrate, each second electronic device including a second region comprising at least one second conductive layer projecting from the semiconductor substrate; and
forming second protective spacers adjacent sidewalls of the second regions of the plurality of second electronic devices, the second protective spacers defined by other portions of second sealing layer and having a thickness less than a thickness of the first sealing layer.

2. A method according to claim 1, wherein the second sealing layer covers top portions of the second regions of the plurality of second electronic devices.

3. A method according to claim 1, wherein the second sealing layer is directly on the first sealing layer.

4. A method according to claim 1, wherein the first sealing layer is also between top portions of the plurality of second electronic devices and the second sealing layer.

5. A method according to claim 1, wherein the first sealing layer is adjacent the semiconductor substrate between the plurality of first electronic devices.

6. A method according to claim 1, wherein the plurality of first electronic devices comprises a plurality of non-volatile memory cells; and wherein the at least one first conductive layer projecting from said semiconductor substrate forms gate regions for the plurality of non-volatile memory cells.

7. A method according to claim 1, wherein the plurality of second electronic devices comprises a plurality of transistors; and wherein the conductive layer projecting from said semiconductive substrate forms gate regions for said plurality of transistors.

8. A method according to claim 1, wherein a thickness of the first sealing layer is within a range of about 3 to 15 nm.

9. A method according to claim 1, wherein a thickness of the second sealing layer is within a range of about 1 to 3 nm.

10. A method according to claim 1, wherein an insulating layer isolates the first region and the first sealing layer from the semiconductor substrate.

11. An integrated circuit comprising:
a semiconductor substrate including first and second portions;
a plurality of first electronic devices adjacent the first portion of said semiconductor substrate, each first electronic device including a first region comprising at least one first conductive layer projecting from said semiconductor substrate;
first protective spacers adjacent sidewalls of the first regions of said plurality of first electronic devices, and defined by first and second sealing layers adjacent one another;
a plurality of second electronic devices adjacent the second portion of said semiconductor substrate, each second electronic device including a second region comprising at least one second conductive layer projecting from said semiconductor substrate; and
second protective spacers adjacent sidewalls of the second regions of said plurality of second electronic devices, and defined by other portions of said second sealing layer, said second sealing layer having a thickness less than a thickness of said first sealing layer.

12. An integrated circuit according to claim 11, wherein said second sealing layer covers top portions of the second regions of said plurality of second electronic devices.

13. An integrated circuit according to claim 11, wherein said second sealing layer is directly on said first sealing layer.

14. An integrated circuit according to claim 11, wherein said first sealing layer is also between top portions of said plurality of second electronic devices and said second sealing layer.

15. An integrated circuit according to claim 11, wherein said first sealing layer is adjacent said semiconductor substrate between said plurality of first electronic devices.

16. An integrated circuit according to claim 11, wherein said plurality of first electronic devices comprises a plurality of non-volatile memory cells; and wherein said at least one first conductive layer projecting from said semiconductor substrate forms gate regions for said plurality of non-volatile memory cells.

17. An integrated circuit according to claim 11, wherein said plurality of second electronic devices comprise a plurality of transistors; and wherein said at least one second conductive layer projecting form said semiconductive substrate forms gate regions for said plurality of transistors.

18. An integrated circuit according to claim 11, wherein a thickness of said first sealing layer is within a range of about 3 to 15 nm.

19. An integrated circuit according to claim 11, wherein a thickness of said second sealing layer is within a range of about 1 to 3 nm.

20. An integrated circuit according to claim 11, wherein an insulating layer isolates said first region and said first sealing layer from said semiconductor substrate.

21. An integrated circuit comprising:
a semiconductor substrate including first and second portions;
an insulating layer adjacent the first portion of said semiconductor substrate;
a plurality of first electronic devices adjacent said dielectric layer, each first electronic device including a first region comprising at least one first conductive layer projecting from said dielectric layer;
a first sealing layer adjacent said plurality of first electronic devices;
a plurality of second electronic devices adjacent the second portion of said semiconductor substrate, each second electronic device including a second region comprising at least one second conductive layer projecting from said semiconductor substrate; and
a second sealing layer adjacent said plurality of second electronic devices and adjacent said first sealing layer sealing, said second sealing layer having a thickness less than a thickness of said first sealing layer.

22. An integrated circuit according to claim 21, wherein said second sealing layer is directly on said first sealing layer.

23. An integrated circuit according to claim 21, wherein said first sealing layer is adjacent said insulating layer between said plurality of first electronic devices.

24. An integrated circuit according to claim 21, wherein said first sealing layer is also between said plurality of second electronic devices and said second sealing layer.

25. An integrated circuit according to claim 21, wherein said second sealing layer is adjacent sidewalls of said plurality of second regions.

26. An integrated circuit according to claim 21, wherein said plurality of first electronic devices comprises a plurality of non-volatile memory cells; and wherein said at least one first conductive layer projecting from said semiconductor substrate forms gate regions for said plurality of non-volatile memory cells.

27. An integrated circuit according to claim 21, wherein said plurality of second electronic devices comprise a plurality of transistors; and wherein the at least one second conductive layer projecting from said semiconductive substrate forms gate regions for said plurality of transistors.

28. An integrated circuit according to claim 21, wherein a thickness of said first sealing layer is within a range of about 3 to 7 nm.

29. An integrated circuit according to claim 21, wherein a thickness of said second sealing layer is within a range of about 1 to 3 nm.
